(19) United States
(12) Patent Application Publication
(10) Pub. No.: US 2018/0197608 A1
(43) Pub. Date: Jul. 12, 2018

(54) HIGH VOLTAGE SWITCH CIRCUITS OF NONVOLATILE MEMORY DEVICES AND NONVOLATILE MEMORY DEVICES

(71) Applicant: SAMSUNG ELECTRONICS CO., LTD., Suwon-si (KR)

(72) Inventors: Jung-Ho SONG, Anyang-si (KR); Tae-Hong KWON, Seoul (KR); Yo-Han LEE, Incheon (KR)

(21) Appl. No.: 15/834,142

(22) Filed: Dec. 7, 2017

(30) Foreign Application Priority Data
Jan. 9, 2017 (KR) 10-2017-0002752

(51) Int. Cl. G11C 16/08; G11C 16/04; G11C 16/12

(52) U.S. Cl. CPC G11C 16/08; H01L 27/11556; G11C 16/12; G11C 16/0483

(57) ABSTRACT

A high voltage switch circuit of a nonvolatile memory device includes a high voltage transistor, logic, and a high voltage switch. The high voltage transistor is turned-on based on a program turn-on voltage and transfers a program voltage to a first memory block. The logic generates path selection signals based on an enable signal and switching control signals based on one of an operating parameter of the nonvolatile memory device or an access address for at least a portion of the first memory block. The enable signal is activated during a program operation on the first memory block. The high voltage switch delivers the program turn-on voltage to a gate of the high voltage transistor via one of a plurality of delivery paths based on the path selection signals. As a result, influence of a negative bias temperature instability (NBTI) generated by the program turn-on voltage is dispersed.

### CROSS-REFERENCE TO RELATED APPLICATION

Korean Patent Application No. 10-2017-0002752, filed on Jan. 9, 2017, and entitled, “High Voltage Switch Circuits of Nonvolatile Memory Devices and Nonvolatile Memory Devices,” is incorporated by reference herein in its entirety.

### BACKGROUND

### 1. Field

One or more embodiments described herein relate to high voltage switch circuits of nonvolatile memory devices and nonvolatile memory devices.

### 2. Description of the Related Art

Semiconductor memory devices may be classified into volatile semiconductor memory devices and nonvolatile semiconductor memory devices. One example of a nonvolatile semiconductor memory device is a flash memory device. A flash memory device may be used to store voice, image, and other data for a variety of electronic products, including but not limited to computers, cellular phones, personal digital assistants, digital cameras, camcorders, voice recorders, MP3 players, handheld personal computers, game machines, facsimile machines, scanners, and printers.

In one type of application, a voltage higher than a power supply voltage is provided to a flash memory device from an external device. A high voltage of about 20V may be used to program and erase memory cells of the flash memory device. A high voltage switch for controlling the high voltage may also be provided. However, when the high voltage is continuously applied to the high voltage switch, the switch may degrade or deteriorate, for example, due to a negative bias temperature instability.

### SUMMARY

In accordance with one or more embodiments, a high voltage switch circuit of a nonvolatile memory device including a plurality of memory blocks, the high voltage switch circuit including a high voltage n-channel metal-oxide semiconductor (NMOS) transistor to be turned-on based on a program turn-on voltage and to transfer a program voltage to a first memory block of the plurality of memory blocks; a logic to generate a plurality of path selection signals based on an enable signal and a plurality of switching control signals based on one of an operating parameter of the nonvolatile memory device or an access address for at least a portion of the first memory block, the enable signal to be activated during a program operation on the first memory block; and a high voltage switch to deliver the program turn-on voltage to a gate of the high voltage NMOS transistor via one of a plurality of delivery paths based on the path selection signals.

In accordance with one or more other embodiments, a nonvolatile memory device includes a memory cell array including a plurality of memory blocks; a voltage generator to generate word-line voltages to be applied to the memory cell array; an address decoder connected to the memory cell array through a plurality of word-lines; a voltage switching circuit to transfer the word-line voltages to the address decoder; and a controller to control the voltage generator, the voltage switching block, and the address decoder based on a command and an address, wherein the voltage switching circuit includes a high voltage switch circuit to deliver a program voltage and a program turn-on voltage from the voltage generator to a first memory block of the memory blocks, via one of a plurality of delivery paths, based on an enable signal and a plurality of switching control signals based on one of an operating parameter of the nonvolatile memory device and an access address for at least a portion of the first memory block, the enable signal to be activated during a program operation on the first memory block.

In accordance with one or more other embodiments, an apparatus includes a first transistor to be turned-on based on a program turn-on voltage, the first transistor to transfer a program voltage to a first memory block of a nonvolatile memory device; logic to generate a plurality of path selection signals based on an enable signal and a plurality of switching control signals based on one of an operating parameter of the nonvolatile memory device or an access address for at least a portion of the first memory block, the enable signal to be activated during a program operation on the first memory block; and a switch to deliver the program turn-on voltage to a gate of the first transistor via one of a plurality of delivery paths based on the path selection signals.

### BRIEF DESCRIPTION OF THE DRAWINGS

Features will become apparent to those of skill in the art by describing in detail exemplary embodiments with reference to the attached drawings in which:

FIG. 1 illustrates an embodiment of a memory system;

FIG. 2 illustrates an embodiment of control signals for the memory system;

FIG. 3 illustrates an embodiment of nonvolatile memory device;

FIG. 4 illustrates an embodiment of a memory cell array;

FIG. 5 illustrates an embodiment of a memory block;

FIG. 6 illustrates an embodiment of an equivalent circuit of a memory block;

FIG. 7 illustrates an embodiment of a control circuit;

FIG. 8 illustrates an embodiment of a switching signal generator;

FIG. 9 illustrates an embodiment of a voltage generator;

FIG. 10 illustrates an embodiment of a program voltage generator;

FIG. 11 illustrates an embodiment of a voltage switching circuit;

FIG. 12 illustrates an embodiment of a high voltage switch circuit;

FIG. 13 illustrates another embodiment of a high voltage switch circuit;

FIG. 14 illustrates another embodiment of a high voltage switch circuit;

FIG. 15 illustrates another embodiment of a high voltage switch circuit;

FIG. 16 illustrates an embodiment of a high voltage switch;

FIG. 17 illustrates an example of negative bias temperature instability (NBTI) in a high voltage PMOS transistor in a high voltage switch;

FIG. 18 illustrates an example of a switching characteristic of the high voltage PMOS transistor resulting from the NBTI;

FIG. 19A illustrates an example of performance of the high voltage switch circuit of FIG. 12, and FIG. 19B illustrates an example of performance of the high voltage switch circuits in FIGS. 13 and 14;

FIG. 20 illustrates an embodiment of the nonvolatile memory device in FIG. 3;

FIG. 21 illustrates an embodiment of a method for operating a nonvolatile memory device; and

FIG. 22 illustrates an embodiment of a solid state disk or solid state drive (SSD).

### DETAILED DESCRIPTION

FIG. 1 illustrates an embodiment of a memory system (or a nonvolatile memory system) 10 may include a memory controller 20 and at least one nonvolatile memory device 30. The memory system 10 may include flash-memory-based data storage media, which, for example, may be or be embodied in a memory card, a universal serial bus (USB) memory and solid state drive (SSD).

The nonvolatile memory device 30 may perform an erase operation, a program operation, or a write operation under control of memory controller 20. The nonvolatile memory device 30 receives a command CMD, an address ADDR, and data DATA through input/output lines from memory controller 20 for performing such operations. In addition, the nonvolatile memory device 30 receives a control signal CTRL through a control line from memory controller 20. In addition, the nonvolatile memory device 30 receives a power PWR through a power line from the memory controller 20.

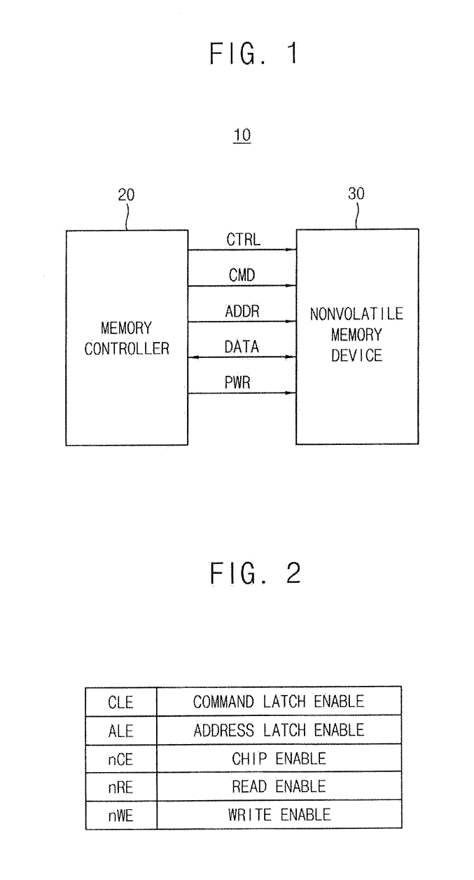

FIG. 2 illustrates an example of a table of control signals in the memory system of FIG. 1. Referring to FIGS. 1 and 2, the control signal CTL (which the memory controller 20 applies to the nonvolatile memory device 30) may include a command latch enable signal CLE, an address latch enable signal ALE, a chip enable signal nCE, a read enable signal nRE, and a write enable signal new.

The memory controller 20 may transmit the command latch enable signal CLE to the nonvolatile memory device 30. The command latch enable signal CLE may indicate that information transferred via the input/output lines is a command. The memory controller 20 may transmit the address latch enable signal ALE to the nonvolatile memory device 30. The address latch enable signal ALE may indicate that information transferred via the input/output lines is an address.

The memory controller 20 may transmit the chip enable signal nCE to the nonvolatile memory device 30. The chip enable signal nCE may indicate a memory chip of a plurality of memory chips when the nonvolatile memory device includes multiple memory chips. The memory controller 20 may transmit the read enable signal nRE to the nonvolatile memory device 30. The nonvolatile memory device 30 may transmit read data to the memory controller 20 based on the read enable signal nRE.

The memory controller 20 may transmit the write enable signal nWE to the nonvolatile memory device 30. When the write enable signal nWE is activated, the nonvolatile memory device 30 may store data input signals from the memory controller 20 as a command CMD or an address ADDR.

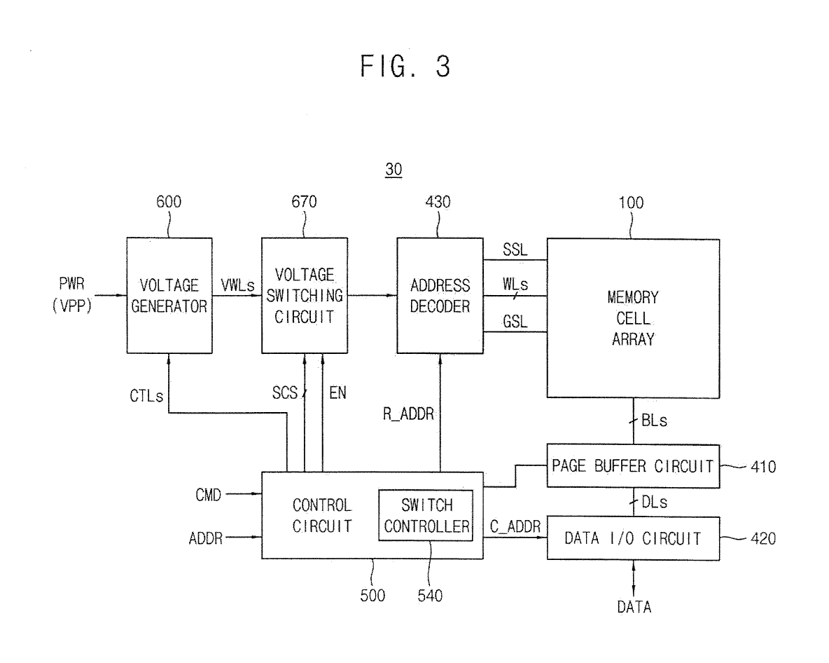

FIG. 3 illustrates an embodiment of a nonvolatile memory device, which, for example, may be the nonvolatile memory device 30 in the memory system of FIG. 1.

Referring to FIG. 3, the nonvolatile memory device 30 includes a memory cell array 100, an address decoder 430, a page buffer circuit 410, a data input/output circuit 420, a control circuit (e.g., controller) 500, a voltage generator 600, and a voltage switching circuit 670. The control circuit 500 may include a high voltage switch controller 540.

The memory cell array 100 may be coupled to the address decoder 430 through a string selection line SSL, a plurality of word-lines WLs, and a ground selection line GSL. The memory cell array 100 may be coupled to the page buffer circuit 410 through a plurality of bit-lines BLs. The memory cell array 100 may include a plurality of memory cells coupled to the word-lines WLs and the bit-lines BLs.

In some exemplary embodiments, the memory cell array 100 may be a three-dimensional memory cell array formed on a substrate with a three-dimensional structure (or a vertical structure). In this case, the memory cell array 100 may include vertical cell strings that are vertically oriented, e.g., at least one memory cell is located over another memory cell. In other exemplary embodiments, the memory cell array 100 may be a two-dimensional memory cell array formed on a substrate in a two-dimensional structure (or a horizontal structure).

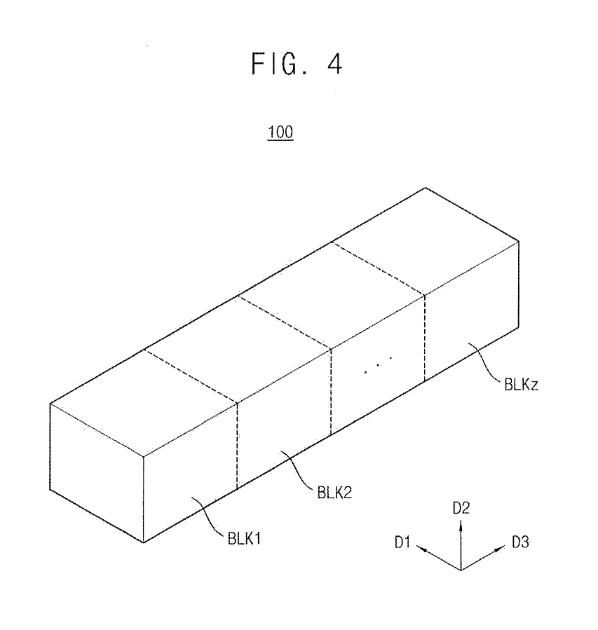

FIG. 4 illustrates an embodiment of a memory cell array, which, for example, may correspond to the memory cell array 100 in FIG. 3. Referring to FIG. 4, the memory cell array 100 may include a plurality of memory blocks BLK1 to BLKz. In an embodiment, the memory blocks BLK1 to BLKz are selected by the address decoder 430 in FIG. 3. The address decoder 430 may, for example, select a memory block BLK, among the memory blocks BLK1 to BLKz, corresponding to a block address.

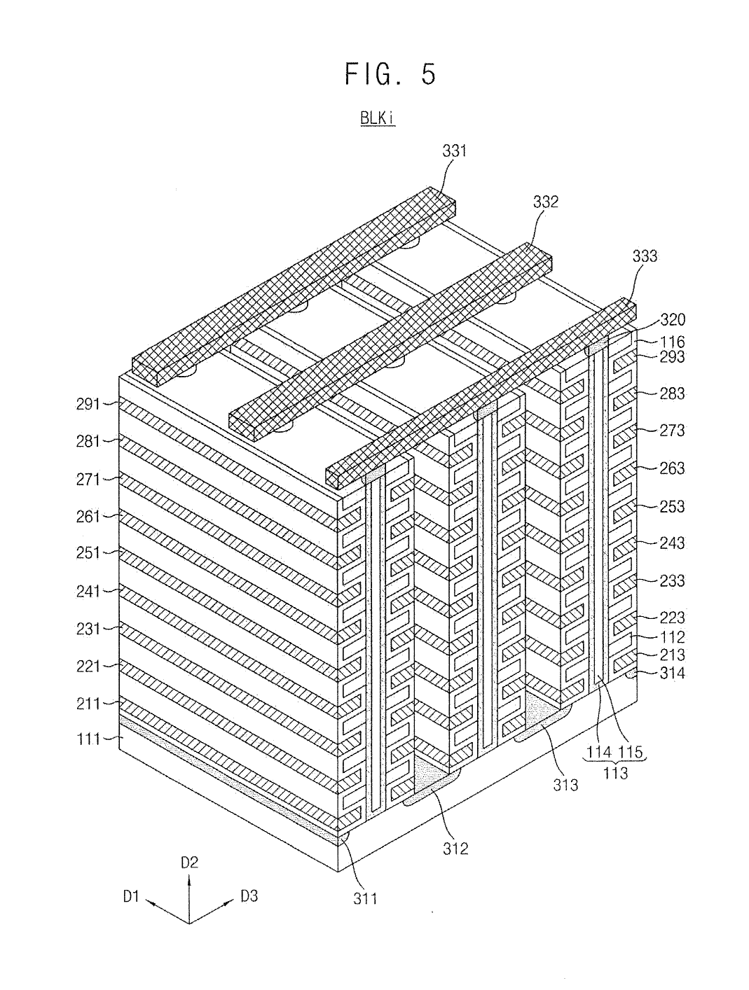

FIG. 5 illustrates an embodiment of one of the memory blocks BLKi of FIG. 4. Referring to FIG. 5, the memory block BLKi includes cell strings formed on a substrate 111 in a three-dimensional structure (or a vertical structure). The memory block BLKi includes structures extending along the first to third directions D1-D3.

The substrate 111 may have, for example, a well of a first conductivity type. For example, the substrate 111 may have a p-well formed by implanting a Group III element such as boron (B). For example, the substrate 111 may have a pocket p-well in an n-well. In an embodiment, the substrate 111 has a p-type well (or a p-type packet well). The conductivity type of the substrate 111 may be different in another embodiment, e.g., n-type.

A plurality of doping regions 311 to 314 extending along the first direction D1 are on the substrate 111. The plurality of doping regions 311 to 314 may have, for example, a second conductivity type different from the first type of the substrate 111. In an embodiment, the first to fourth doping regions 311 to 314 be an n-type. In another embodiment, the first to fourth doping regions 311 to 314 may be a p-type.

A plurality of insulation materials 112 extend along the first direction D1 and are sequentially provided along the second direction D2 on a region of the substrate 111 between the first and second doping regions 311 and 312. The insulation materials may be, for example, provided along the second direction D2 and spaced by a specific distance. The insulation materials 112 may include, for example, an oxide layer.

A plurality of pillars 113 may penetrate the insulation materials along the second direction D2 and may be sequentially disposed along the first direction on a region of the substrate 111 between the first and second doping regions 311 and 312. The pillars 113 may penetrate, for example, the insulation materials 112 in order to contact the substrate 111.

Each pillar 113 may include, for example, a plurality of materials. For example, a channel layer 114 of each pillar 113 may include a silicon material of a first conductivity type. In one embodiment, the channel layer 114 of each pillar 113 may include a silicon material having the same conductivity type as the substrate 111. In one embodiment, the channel layer 114 of each pillar 113 includes p-type silicon. In one embodiment, the channel layer 114 of each pillar 113 may include n-type material.

An internal material 115 of each pillar 113 includes an insulation material. For example, the internal material 115 of each pillar 113 may include silicon oxide. In one embodiment, the inner material 115 of each pillar 113 may include an air gap.

An insulation layer 116 is provided along the exposed surfaces of the insulation materials 112, the pillars 113, and the substrate 111, on a region between the first and second doping regions 311 and 312. The insulation layer 116 on the exposed surface in the second direction D2 of the last insulation material 112 may be removed.

First conductive materials 211 to 291 are provided on the exposed surface of the insulation layer 116 in a region between the first and second doping regions 311 and 312. For example, the first conductive material 211 extending along the first direction D1 may be between the insulation material 112 adjacent to the substrate 111 and the substrate 111. In one embodiment, the first conductive material 211 extending along the first direction D1 may be between the insulation layer 116 at the bottom of the insulation material 112 adjacent to the substrate 111 and the substrate 111.

A first conductive material extending along the first direction D1 is between the insulation layer 116 at the top of the specific insulation material among the insulation materials 112 and the insulation layer at the bottom of the insulation material on the top of the specific insulation material. For example, a plurality of first conductive materials 221 to 281 extending along the first direction D1 are between the insulation materials 112, and it may be understood that the insulation layer 116 is between the insulation materials 112 and the first conductive materials 221 to 281. The first conductive materials 211 to 291 may include a metal material. The first conductive materials 211 to 291 may include a conductive material such as a polysilicon.

The same structures as those on the first and second doping regions 311 and 312 may be in a region between the second and third doping regions 312 and 313. The region between the second and third doping regions 312 and 313 may include a plurality of insulation materials 112 extending along the first direction D1, a plurality of pillars 113 disposed sequentially along the first direction D1 and penetrating the insulation materials 112 along the third direction D3, an insulation layer 116 on the exposed surfaces of the insulation materials 112 and the pillars 113, and a plurality of conductive materials 212 to 292 extending along the first direction. A region between the third and fourth doping regions 313 and 314 may include the same structures as those on the first and second doping regions 311 and 312. The region between the third and fourth doping regions 313 and 314 may include a plurality of insulation materials 112 extending along the first direction D1, a plurality of pillars 113 disposed sequentially along the first direction and penetrating the insulation materials 112 along the third direction D3, an insulation layer 116 on the exposed surfaces of the insulation materials 112 and the pillars 113, and a plurality of first conductive materials 213 to 293 extending along the first direction D1.

Drains 320 are on respective ones of the pillars 113. The drains 320 may include silicon materials doped with a second conductivity type. For example, the drains 320 may include silicon materials doped with an n-type conductivity. In an embodiment, the drains 320 include n-type silicon materials. The drains 320 may include p-type conductivity silicon materials in another embodiment. The second conductivity materials 331 to 333 extending along the third direction D3 are on the drains. The second conductive materials 331 to 333 are disposed along the first direction D1 and spaced by a specific distance. The second conductive materials 331 to 333 are respectively connected to the drains 320 in a corresponding region. The drains 320 and the second conductive material 333 extending along the third direction D3 may be connected through one or more corresponding contact plugs. The second conductive materials 331 to 333 may include metal materials. In one embodiment, the second conductive materials 331 to 333 may include conductive materials such as a polysilicon.

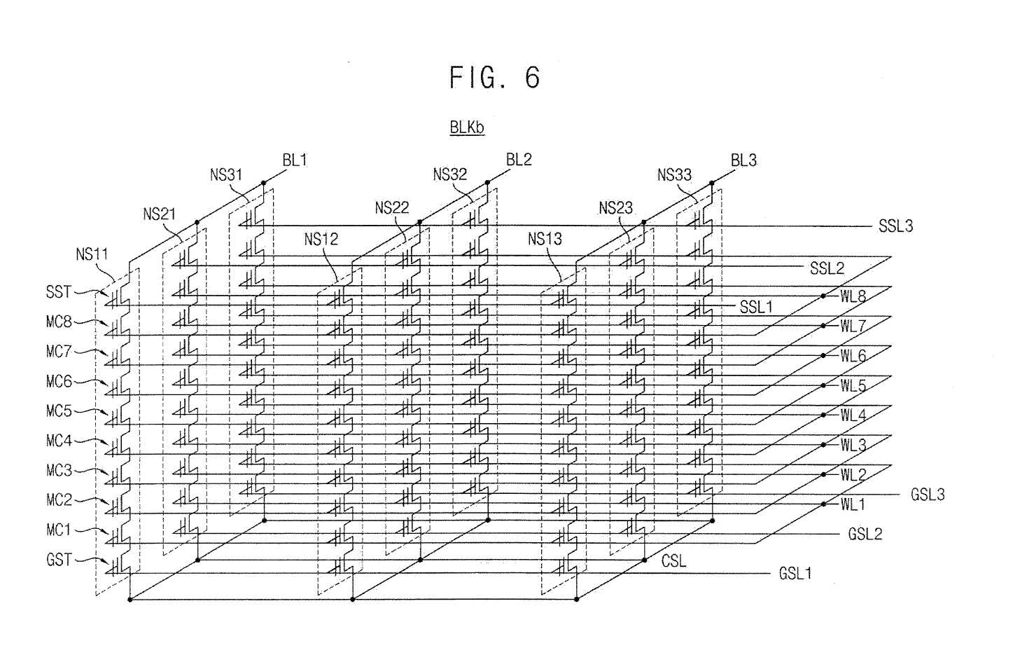

FIG. 6 illustrates an embodiment of an equivalent circuit of the memory block BLKi in FIG. 5. The memory block BLKi may be formed on a substrate in a three-dimensional structure (or a vertical structure). A plurality of memory cell strings in the memory block BLKi may be formed in a direction perpendicular to the substrate.

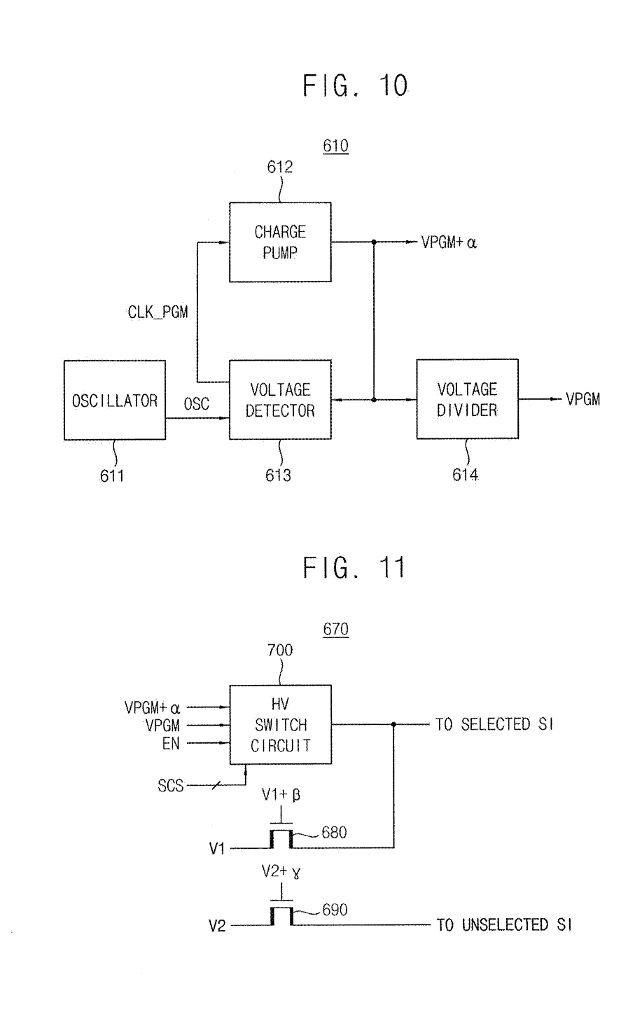

Referring to FIG. 6, the memory block BLKi may include memory cell strings NS11 to NS33 coupled between bit-lines BL1, BL2 and BL3 and a common source line CSL. Each of the memory cell strings NS11 to NS33 may include a string selection transistor SST, a plurality of memory cells MC1 to MC8, and a ground selection transistor GST. In FIG. 10, each of the memory cell strings NS11 to NS33 is illustrated to include eight memory cells MC1 to MC8. Each of the memory cell strings NS11 to NS33 may include a different number of memory cells in another embodiment.

The string selection transistor SST may be connected to corresponding string selection lines SSL1 to SSL3. The memory cells MC1 to MC8 may be connected to corresponding word-lines WL1 to WL8, respectively. The ground selection transistor GST may be connected to corresponding ground selection lines GSL1 to GSL3. The string selection transistor SST may be connected to corresponding bit-lines BL1, BL2 and BL3. The ground selection transistor GST may be connected to the common source line CSL.

Word-lines (e.g., WL1) having the same height may be commonly connected. The ground selection lines GSL1 to GSL3 and the string selection lines SSL1 to SSL3 may be separated. In FIG. 6, the memory block BLKb is coupled to eight word-lines WL1 to WL8 and three bit-lines BL1 to BL3. The memory cell array 100a may be coupled to a different number of word-lines and bit-lines in another embodiment.

Referring back to FIG. 3, the control circuit 500 may receive a command (signal) CMD and an address (signal) ADDR from the memory controller 20 and control an erase loop, a program loop, and a read operation of the nonvolatile memory device 30 based on the command signal CMD and the address signal ADDR. The program loop may include a program operation and a program verification operation. The erase loop may include an erase operation and an erase verification operation. The read operation may include a normal read operation and data recover read operation.

The control circuit 500 may generate control signals CTLs, which, for example, are used to control the voltage generator 600 based on the command signal CMD and to generate a row address R_ADDR and a column address C_ADDR based on the address signal ADDR. The control circuit 500 may provide the row address R_ADDR to the address decoder 430 and provide the column address C_ADDR to the data input/output circuit 420. The control circuit 500 may generate an enable signal EN which is activated when the command CMD designates a program operation on one of the memory blocks BLK1-BLKz, and may generate a plurality of switching control signals SCS to reflect one of an operating parameter of the nonvolatile memory device 30 and the row address (or an access address) R_ADDR.

The address decoder 430 may be coupled to the memory cell array 100 through the string selection line SSL, the word-lines WLs, and the ground selection line GSL. During the program operation or the read operation, the address decoder 430 may determine one of the word-lines WLs as a selected word-line and determine remaining word-lines WLs as unselected word-lines based on the row address R_ADDR.

The voltage generator 600 may generate word-line voltages VWLs based on the control signals CTLs from control circuit 500. The word-line voltages VWLs are used for operation of the nonvolatile memory device 30 based on the power PWR from the memory controller 20 or the power supply voltage VPP. The word-line voltages VWLs may be applied to the word-lines WLs through the voltage switching circuit 670 and the address decoder 430.

During the erase operation, for example, the voltage generator 600 may apply an erase voltage to a well of the memory block and may apply a ground voltage to all of the word-lines of the memory block. During the erase verification operation, the voltage generator 600 may apply an erase verification voltage to all of the word-lines of the memory block or may sequentially apply the erase verification voltage to word-lines on a word-line-by-word-line basis.

During the program operation, for example, the voltage generator 600 may apply a program voltage to the selected word-line and may apply a program pass voltage to the unselected word-lines. In addition, during the program verification operation, the voltage generator 600 may apply a program verification voltage to the first word-line and may apply a verification pass voltage to the unselected word-lines.

During the read operation, for example, the voltage generator 600 may apply a read voltage to the selected word-line and may apply a read pass voltage to the unselected word-lines.

The page buffer circuit 410 may be coupled to the memory cell array 100 through the bit-lines BLs. The page buffer circuit 410 may include a plurality of page buffers. In some exemplary embodiments, one page buffer may be connected to one bit-line. In some exemplary embodiments, one page buffer may be connected to two or more bit-lines. The page buffer circuit 410 may temporarily store data to be programmed in a selected page during the program operation or data read out from the selected page during the read operation.

The data input/output circuit 420 may be coupled to the page buffer circuit 410 through data lines DLs. During the program operation, the data input/output circuit 420 may receive program data DATA from the memory controller 20 and may provide the program data DATA to the page buffer circuit 410 based on the column address C_ADDR from the control circuit 450. During the read operation, the data input/output circuit 420 may provide read data DATA, which is stored in the page buffer circuit 410, to the memory controller 20 based on the column address C_ADDR from the control circuit 500.

In addition, the page buffer circuit 410 and the data input/output circuit 420 read data from a first area of the memory cell array 100 and write the read data to a second area of the memory cell array 100. For example, the page buffer circuit 410 and the data input/output circuit 420 may perform a copy-back operation.

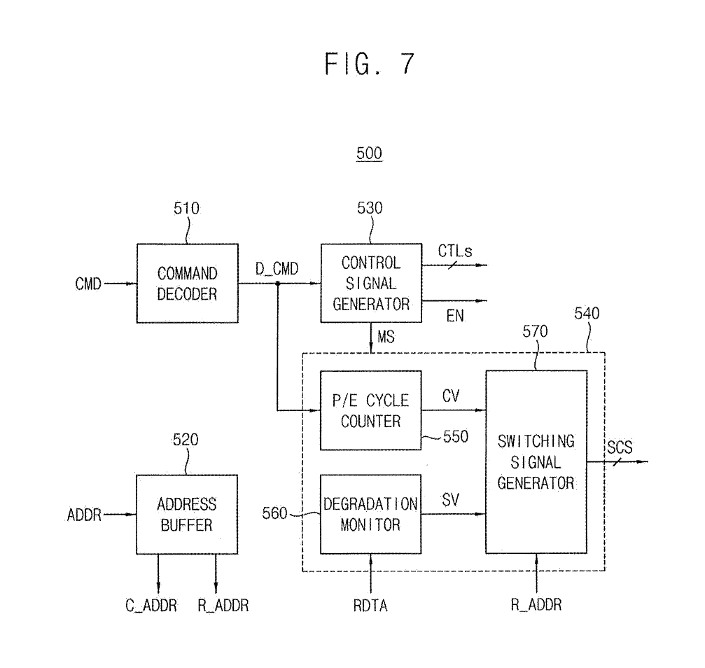

FIG. 7 illustrates an embodiment of a control circuit, which, for example, may corresponding to control circuit 500 in the nonvolatile memory device of FIG. 3.

Referring to FIG. 7, the control circuit 500 may include a command decoder 510, an address buffer 520, a control signal generator 530, and a high voltage switch controller 540. The high voltage switch controller 540 may include a program/erase cycle counter 550, a degradation monitor 560, and a switching signal generator 570.

The command decoder 510 decodes the command CMD and provides a decoded command D_CMD to the control signal generator 530. The command decoder 510 provides the decoded command D_CMD to the program/erase cycle counter 550 when the decoded command D_CMD is a program command or an erase command.

The address buffer 520 receives the address signal ADDR, provides the row address R_ADDR to the address decoder 430 and the switching signal generator 570, and provides the column address C_ADDR to the data input/output circuit 420.

The control signal generator 530 receives the decoded command D_CMD and the comparison signal CS, generates the control signals CTLs based on an operation directed by the decoded command D_CMD and provides the control signals CTLs to the voltage generator 600. When the decoded command D_CMD is a program command, the control signal generator 530 generates a mode signal MS indicating a selection mode in the decoded command D_CMD, provides the mode signal MS to the high voltage switch controller 540, and provides the high voltage switch controller 540 with the enable signal EN which is activated when the decoded command D_CMD is a program command.

When the mode signal MS designates a first selection mode in the program operation, the switching signal generator 570 may generate the switching control signals SCS based on a portion of bits of the row address R_ADDR. For example, the switching signal generator 570 may generate the switching control signals SCS based on one or two least significant bits of the row address R_ADDR. The row address R_ADDR may be replaced with a block address to designate one memory block or a page address to designate one of pages in one memory block.

When the mode signal MS designates a second selection mode in the program operation, the program/erase cycle counter 550 counts a number of program/erase cycles on the selected memory block based on the decoded command D_CMD and provides the switching signal generator 570 with a counting value CV which indicates the counted number of the program/erase cycles on the selected memory block. The switching signal generator 570 generates the switching control signals SCS based on the counting value CV.

When the mode signal MS designates a third selection mode in the program operation, the degradation monitor 560 receives data RDTA read from at least one reference memory cell in the selected memory block, determines a degradation degree of the reference memory cell based on the read data RDTA, and provides the switching signal generator 570 with a stress index SV which indicates the degradation degree. The switching signal generator 570 generates the switching control signals SCS based on the stress index SV.

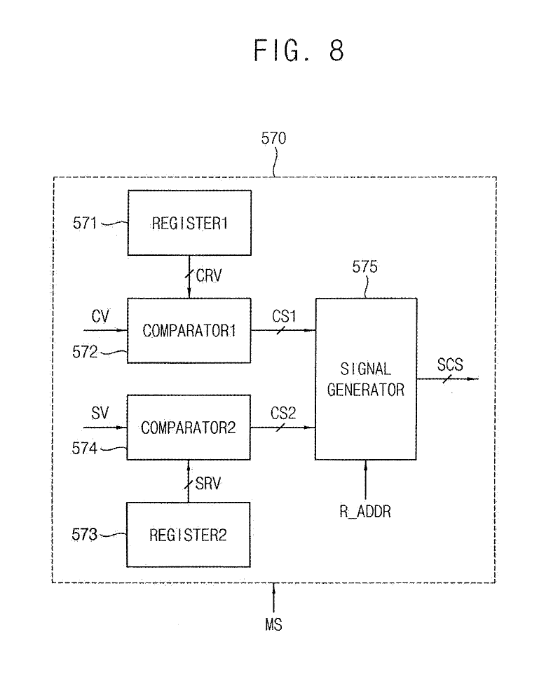

FIG. 8 illustrates an embodiment of a switching signal generator, which, for example, may be the switching signal generator 570 in the control circuit of FIG. 7.

Referring to FIG. 8, the switching signal generator 570 receives the mode signal MS and includes a first register 571, a first comparator 572, a second register 573, a second comparator 574, and a signal generator 575. The first register 571 stores at least one first reference value CRV associated with the number of the program/erase cycles and provides the first reference value CRV to the first comparator 572. The first reference value CRV may be used as a basis for determining a range of the number of the program/erase cycles on one memory block. The first comparator 572 compares the counting value CV and the at least one first reference value CRV and provides the signal generator 575 with a first comparison signal CS1 indicating a result of comparison of the counting value CV and the at least one first reference value CRV. The first comparison signal CS1 includes one or more bits.

The second register 573 stores at least one second reference value SRV associated with the degradation degree of the reference memory cell and provides the second reference value SRV to the second comparator 574. The second reference value SRV may be a value to determine a range of the degradation degree of the reference memory cell. The second comparator 574 compares the stress index SV and the at least one second reference value SRV and provides the signal generator 575 with a second comparison signal CS2 indicating a result of comparison of the stress index SV and the at least one second reference value SRV. The second comparison signal CS2 includes one or more bits.

The signal generator 575 receives the row address R_ADDR, the first comparison signal CS1, and the second comparison signal CS2. The signal generator 575 may generate the switching control signals SCS based on one or two least significant bits of the row address R_ADDR in the first selection mode, may generate the switching control signals SCS based on the first comparison signal CS1 in the second selection mode, and may generate the switching control signals SCS based on the second comparison signal CS2 in the third selection mode.

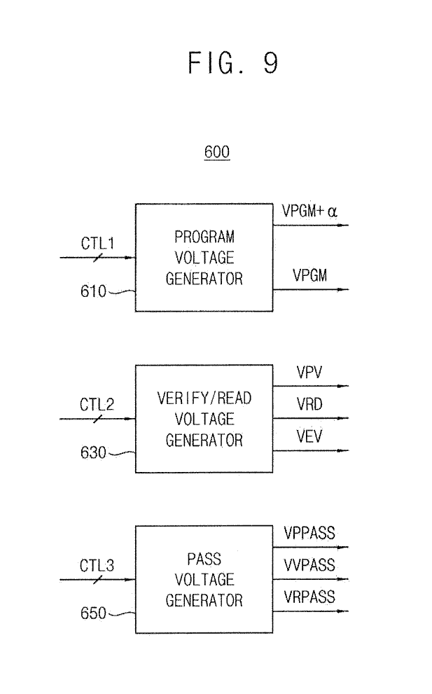

FIG. 9 illustrates an embodiment of a voltage generator, which, for example, may correspond to voltage generator 600 in the nonvolatile memory device of FIG. 3.

Referring to FIG. 9, the voltage generator 600 includes a program voltage generator 610, verify/read voltage generator 630, and a pass voltage generator 650. The program voltage generator 610 may generate a program voltage VPGM and a program turn-on voltage VPGM+α based on a first control signal CTL1 and according to an operation designated by the decoded command D_CMD. The program voltage VPGM may be provided to the selected word-line. The first control signal CTL1 may include a plurality of bits which indicate the operation directed by the decoded command D_CMD.

The verify/read voltage generator 630 may generate a program verify voltage VPV, a read verify voltage VRD, and an erase verify voltage VEV based on a second control signal CTL2 and according to operations designated by the decoded command D_CMD. The program verify voltage VPV, the read verify voltage VRD, and the erase verify voltage VEV may be applied to the selected word-line according to the operations. The second control signal CTL2 may include a plurality of bits which indicate the operations directed by the decoded command D_CMD.

The pass voltage generator 650 may generate a program pass voltage VPPASS, a verify pass voltage VVPASS, and a read pass voltage VRPASS based on a third control signal CTL3 and according to operations designated by the decoded command D_CMD. The program pass voltage VPPASS, the verify pass voltage VVPASS, and the read pass voltage VRPASS may be applied to the unselected word-lines according to the operations. The third control signal CTL3 may include a plurality of bits which indicate the operations directed by the decoded command D_CMD.

FIG. 10 illustrates an embodiment of a program voltage generator, which, for example, may correspond to the program voltage generator in FIG. 9.

Referring to FIG. 10, the program voltage generator 610 includes an oscillator 611, a charge pump 612, a voltage detector 613, and a voltage divider 614. The oscillator outputs an oscillation signal OSC. The charge pump 612 performs a pumping operation based on a pumping clock CLK_PMG to generate the program turn-on voltage VPGM+a. For example, an output voltage may be raised up to the program turn-on voltage VPGM+a by charging serially connected capacitors with predetermined voltage through a pumping operation. The voltage detector 613 receives the oscillation signal OSC and detects an output of the charge pump 612 to generate the pumping clock CLK_PGM. The voltage divider 614 divides the program turn-on voltage VPGM+α to output the program voltage VPGM.

Each of the verify/read voltage generator 630 and the pass voltage generator 650 in FIG. 9 may have a configuration similar to program voltage generator 610 in FIG. 10.

FIG. 11 is a block diagram illustrating the voltage switching circuit in the nonvolatile memory device of FIG. 3 according to exemplary embodiments.

Referring to FIG. 11, the voltage switching circuit 670 includes a high voltage switch circuit 700 and a plurality of high voltage n-channel metal-oxide semiconductor (NMOS) transistors 680 and 690.

The high voltage switch circuit 700 receives the program voltage VPGM and the program turn-on voltage VPGM+α from the program voltage generator 610, receives the enable signal EN and the switching control signals SCS from the control circuit 500, and delivers the program turn-on voltage VPGM+α to an internal high voltage NMOS transistor therein via one of a plurality of delivery paths, based on the switching control signal SCS when the enable signal EN indicates a program operation. A voltage α may have a level equal to or greater than a threshold voltage of the internal high voltage NMOS transistor. Therefore, the high voltage switch circuit 700 may disperse an influence of the NBTI generated by the program turn-on voltage VPGM+a. The high voltage switch circuit 700 may transfer the program voltage VPGM to a selection line (a first selection line) SI connected to a selected word-line of the selected memory block in the program operation.

The high voltage NMOS transistor 680 may transfer a first voltage V1 to the selected selection line based on a first turn-on voltage V1+β. The high voltage NMOS transistor 690 may transfer a second voltage V2 to an unselected selected selection line connected to unselected word-line in the selected memory block based on a second turn-on voltage V1+γ. The first voltage V1 may be a verify voltage or a read voltage and a voltage β may have a level equal to or greater than a threshold voltage of the high voltage NMOS transistor 680. The second voltage V2 may be a pass voltage and a voltage γ may have a level equal to or greater than a threshold voltage of the high voltage NMOS transistor 690.

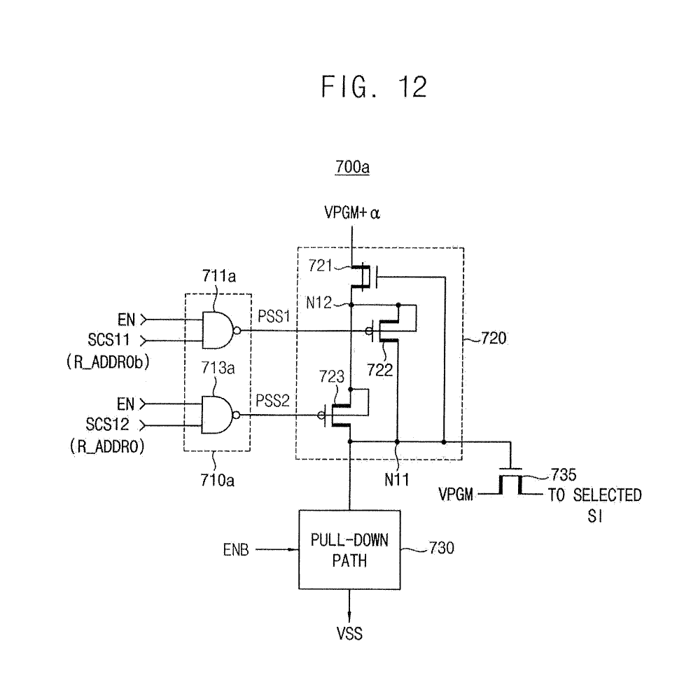

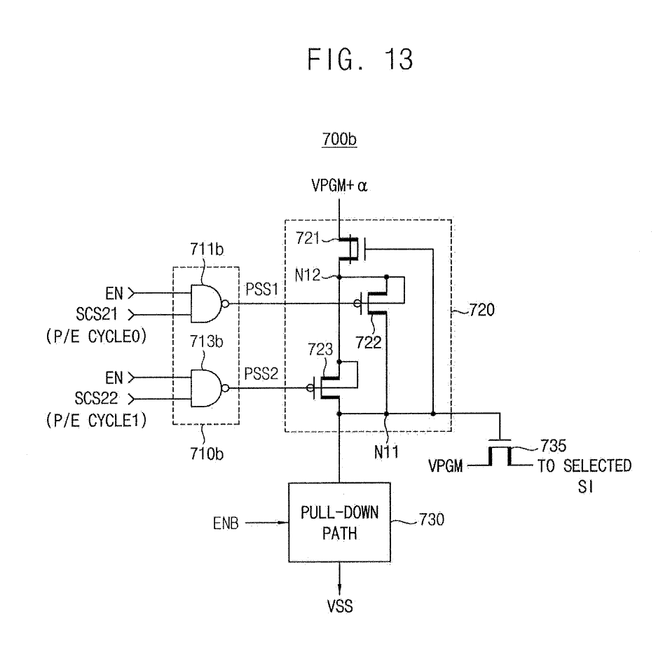

FIG. 12 illustrates an embodiment of a high voltage switch circuit 700a in the voltage switching circuit of FIG. 11.

Referring to FIG. 12, a high voltage switch circuit 700a includes a logic circuit 710a, a high voltage switch 720, a pull-down path 730, and a high voltage NMOS transistor 735. The high voltage NMOS transistor 735 is turned on based on the program turn-on voltage VPGM+α and transfers the program voltage VPGM to the first selection line.

The logic circuit 710a generates a plurality of path selection signals PSS1 and PSS2 based on the enable signal EN which is activated during the program operation and the switching control signals SCS11 and SCS12 based on the access address R_ADDR. The logic circuit 710a includes a first NAND gate 711a and the second NAND gate 713a. The first NAND gate 711a performs a NAND operation on the enable signal EN and a first switching control signal SCS11 to output a first path selection signal PSS1. The first switching control signal SCS11 may have a logic level R_ADDR0b opposite to the logic level of the least significant bit R_ADDR0 of the access address R_ADDR. The second NAND gate 713a performs a NAND operation on the enable signal EN and a second switching control signal SCS12 to output a second path selection signal PSS2. The first switching control signal SCS11 may have a logic level equal to the logic level of the least significant bit R_ADDR0 of the access address R_ADDR.

The high voltage switch 720 includes a depletion NMOS transistor 721, a first high voltage p-channel metal-oxide semiconductor (PMOS) transistor 722, and a second high voltage PMOS transistor 723. The depletion NMOS transistor 721 has a first electrode to receive the program turn-on voltage VPGM+a, a gate connected to a first node N11 connected to a gate of the high voltage NMOS transistor 735, and a second electrode connected to a second node N12. The first high voltage PMOS transistor 722 has a first electrode connected to the second node N12, a second electrode connected to the first node N11, and a gate to receive the first path selections signal PSS1. The second high voltage PMOS transistor 723 has a first electrode connected to the second node N12, a second electrode connected to the first node N11, and a gate to receive the second path selections signal PSS2. A body of each of the first and second high voltage PMOS transistors 722 and 723 is connected to respective first electrode and the first and second high voltage PMOS transistors 722 and 723 connected in parallel between the first node N11 and the second node N12.

The pull-down path 730 is connected between the first node N11 and a ground voltage VSS, is turned on based on an inverted enable signal ENB during memory operations except the program operation, and discharges the first node N11 with the ground voltage VSS.

Since the least significant bit R_ADDR0 of the access address R_ADDR is alternatingly changed whenever the access address R_ADDR sequentially designates pages of the memory block, the first path selection signal PSS1 and the second path selection signal PSS2 may be activated in a complementarily manner based on the logic level of the least significant bit R_ADDR0 of access address R_ADDR. Therefore, a path, through which the program turn-on voltage VPGM+α is delivered to the high voltage NMOS transistor, may be alternatingly selected from a first path through the depletion NMOS transistor 721, the first high voltage PMOS transistor 722 and the first node NI 1 and a second path through the depletion NMOS transistor 721, the second high voltage PMOS transistor 723 and the first node N11, according to the logic level of the least significant bit R_ADDR0 of the access address R_ADDR. Accordingly, the influence of the NBTI due to the program turn-on voltage VPGM+α on the first high voltage PMOS transistor 722 and the second high voltage PMOS transistor 723 due to the NBTI may be substantially reduced, for example, by half.

The depletion NMOS transistor 721 has a negative threshold voltage, is turned on when the first node N11 is discharged with the ground voltage VSS, and transfers the negative threshold voltage to the second node N12. Therefore, when the first path selection signal PSS1 has a low level and the second path selection signal PSS2 has a high level, the first high voltage PMOS transistor 722 is turned-on and the program turn-on voltage VPGM+α is transferred to the first node N11. After the first high voltage PMOS transistor 722 is turned-on based on a voltage difference of the program turn-on voltage VPGM+α at the first node N11 and the a voltage at the second node N12., the second high voltage PMOS transistor 723 is turned on. However, a bias between a channel and the gate of the second high voltage PMOS transistor 723 is smaller than a bias between a channel and the gate of the first high voltage PMOS transistor 722.

In addition, when the first path selection signal PSS1 has a high level and the second path selection signal PSS2 has a low level, both of the first high voltage PMOS transistor 722 and the second high voltage PMOS transistor 723 are turned on, the program turn-on voltage VPGM+α is transferred to the gate of the high voltage NMOS transistor 735, and the high voltage NMOS transistor 735 is turned on in response to the program turn-on voltage VPGM+α.

FIG. 13 illustrates another embodiment of the high voltage switch circuit 700b which includes a logic circuit 710b, a high voltage switch 720, a pull-down path 730 and a high voltage NMOS transistor 735. The high voltage switch circuit 700b of FIG. 13 differs from the high voltage switch circuit 700a of FIG. 12 in that the high voltage switch circuit 700b includes the logic circuit 710b instead of the logic circuit 710a.

The logic circuit 710b generates path selection signals PSS1 and PSS2 based on the enable signal EN activated during the program operation and switching control signals SCS21 and SCS22 reflecting program/erase cycle ranges P/E CYCLE0 and P/E CYCLE1. The logic circuit 710b includes a first NAND gate 711b and the second NAND gate 713b. The first NAND gate 711b performs a NAND operation on the enable signal EN and a first switching control signal SCS21 to output a first path selection signal PSS. The first switching control signal SCS21 may have a high level when the counting value CV of the program/erase cycle belongs to the first range P/E CYCLE0. The second NAND gate 713b performs a NAND operation on the enable signal EN and a second switching control signal SCS22 to output a second path selection signal PSS2. The second switching control signal SCS22 may have a high level when the counting value CV of the program/erase cycle belongs to the second range P/E CYCLE1.

Therefore, the high voltage switch circuit 700b of FIG. 13 may disperse the influence due to the NBTI by transferring the program turn-on voltage VPGM+α via the first path or the second path according to a range to which the counting value CV of the program/erase cycle belongs.

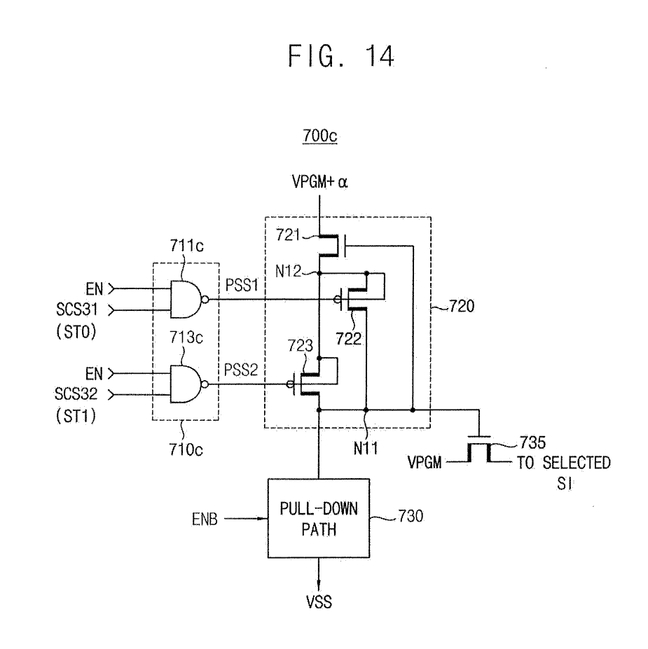

FIG. 14 illustrates another embodiment of a high voltage switch circuit 700c in the voltage switching circuit of FIG. 11. Referring to FIG. 14, the high voltage switch circuit 700c includes a logic circuit 710c, a high voltage switch 720, a pull-down path 730, and a high voltage NMOS transistor 735. The high voltage switch circuit 700c differs from the high voltage switch circuit 700a of FIG. 12 in that the high voltage switch circuit 700b includes the logic circuit 710c instead of the logic circuit 710a.

The logic circuit 710c generates path selection signals PSS1 and PSS2 based on the enable signal EN, which is activated during the program operation, and switching control signals SCS31 and SCS32 reflecting the degradation ranges of the at least one reference memory cell. The logic circuit 710c includes a first NAND gate 711c and the second NAND gate 713c. The first NAND gate 711c performs a NAND operation on the enable signal EN and a first switching control signal SCS31 to output a first path selection signal PSS. The first switching control signal SCS31 may have a high level when the degradation degree belongs to a first range ST0. The second NAND gate 713c performs a NAND operation on the enable signal EN and a second switching control signal SCS32 to output a second path selection signal PSS2. The second switching control signal SCS32 may have a high level when the degradation degree belongs to a second range ST1.

Therefore, the high voltage switch circuit 700c of FIG. 14 may disperse the influence due to NBTI by transferring the program turn-on voltage VPGM+α via the first path or the second path according to a range to which the degradation degree of the at least one reference memory cell belongs.

In FIGS. 12 to 14, the high voltage switch 720 includes two high voltage PMOS transistors and each of the logic circuits 710a, 710b, and 710c includes two NAND gates. In one embodiment, the high voltage switch 720 may include 2^{k} (k is an integer greater than one) high voltage PMOS transistors, and each of the logic circuits 710a, 710b and 710c may include 2^{k} NAND gates. In addition, the switching signal generator 570 in FIG. 7 may generate 2^{k} switching control signals SCS.

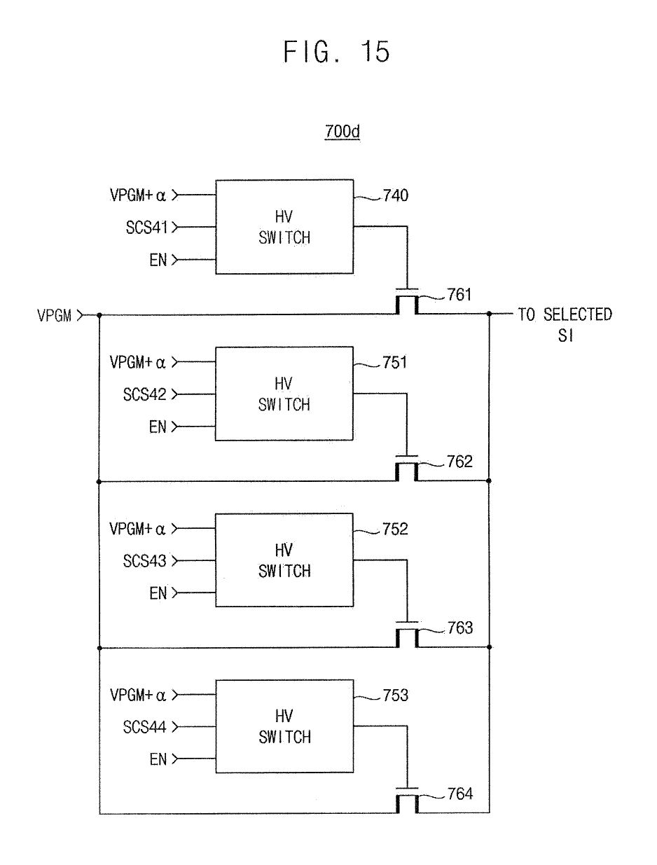

FIG. 15 illustrates another embodiment of a high voltage switch circuit 700d in the voltage switching circuit of FIG. 11. Referring to FIG. 15, the high voltage switch circuit 700d includes a plurality of high voltage NMOS transistors 761, 762, 763, and 764, and a plurality of high voltage switches 740, 751, 752, and 753. The high voltage NMOS transistors 761, 762, 763, and 764 may be connected in parallel to the first selection line connected to the selected memory block. Each of the high voltage switches 740, 751, 752, and 753 may be connected to a gate of a corresponding one of the high voltage NMOS transistors 761, 762, 763, and 764. Each of the high voltage switches 740, 751, 752, and 753 receives the program turn-on voltage VPGM+α, the enable signal EN and a corresponding one of a plurality of switching control signals SCS41, SCS42, SCS43, and SCS44, is turned on based on the corresponding switching control signal and transfers the program turn-on voltage VPGM+α to the corresponding high voltage NMOS transistor. Each of the high voltage NMOS transistors 761, 762, 763, and 764 has a first electrode to receive the program voltage VPGM and a second electrode connected to the first selection line.

Therefore, each of the high voltage switches 740, 751, 752, and 753 is turned on based on a corresponding one of the switching control signals SCS41, SCS42, SCS43, and SCS44, and the high voltage switch circuit 700d transfers the program turn-on voltage VPGM+α via a different path determined by the switching control signals SCS41, SCS42, SCS43, and SCS44. The switching control signals SCS41, SCS42, SCS43, and SCS44 may have alternatingly a high level according to logic levels of the two least significant bits of the access address R_ADDR, according to a range to which the counting value CV of the program/erase cycle belongs, or according to the degradation degree of the at least one reference memory cell belongs, as described with reference to FIGS. 12 to 14. Therefore, the high voltage switch circuit 700c of FIG. 14 may disperse the influence due to NBTI by transferring the program turn-on voltage VPGM+α via a different path based on the switching control signals SCS41, SCS42, SCS43, and SCS44 reflecting the access address during the program operation of the nonvolatile memory device 30 or the operating parameter of the nonvolatile memory device 30.

In FIG. 15, the high voltage switch circuit 700d includes four high voltage NMOS transistors and four high voltage switches. In one embodiment, the high voltage switch circuit 700d may include 2^{k} (k is an integer greater than one) high voltage NMOS transistors and 2^{k} high voltage switches.

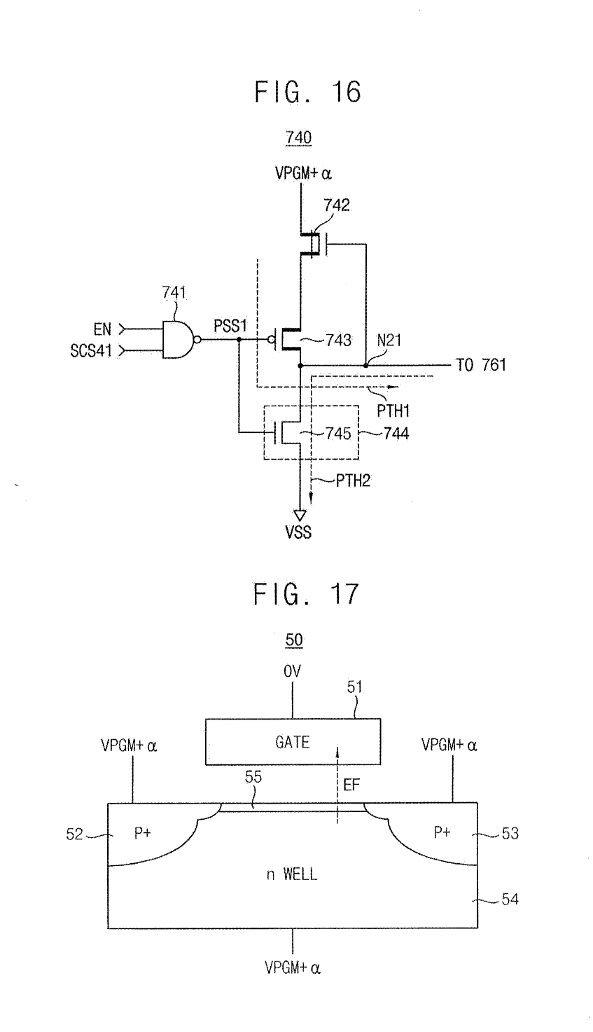

FIG. 16 illustrates an embodiment representative of one or more of the high voltage switches in the high voltage switch circuit of FIG. 15. For illustrative purposes, the configuration of the high voltage switch 740 is illustrated. Each of the high voltage switches 751, 752, and 753 may have a substantially same configuration as the high voltage switch 740.

Referring to FIG. 16, the high voltage switch 740 includes a NAND gate 741, a depletion NMOS transistor 742, a high voltage PMOS transistor 743 and a pull-down path 744, and the pull-down path includes an NMOS transistor 745. The NAND gate 741 performs a NAND operation on the enable signal EN and a first switching control signal SCS41 to output a first path selection signal PSS. The first path selection signal PSS1 is applied to a gate of the high voltage PMOS transistor 743 and a gate of the NMOS transistor 745.

The depletion NMOS transistor 742 has a first electrode to receive the program turn-on voltage VPGM+α, a gate connected to a first node N21 connected to a gate of the high voltage NMOS transistor 761, and a second electrode connected to the high voltage PMOS transistor 743. The high voltage PMOS transistor 743 has a first electrode connected to the depletion NMOS transistor 742, a second electrode connected to the first node N21, and a gate to receive the first path selections signal PSS1. The depletion NMOS transistor 742 has a first electrode connected to the high voltage PMOS transistor 743 at the first node N21, a gate to receive the first path selection signal PSS1, and a second electrode connected to the ground voltage VSS.

When the first path selection signal PSS1 has a low level PSS1 based on the first switching control signal SCS41 during the program operation of the nonvolatile memory device 30, the program turn-on voltage VPGM+α is transferred to the gate of the high voltage NMOS transistor 761 via a first path PTH including the depletion NMOS transistor 742 and the high voltage PMOS transistor 743. When the first path selection signal PSS1 has a high level PSS1 based on the first switching control signal SCS41, the first node N21 is discharged with the ground voltage VSS via a second path PTH2 including the NMOS transistor 745 and the high voltage NMOS transistor 761 is turned off based on the ground voltage VSS at the first node N21.

The high voltage switch circuits 700a-700d of FIGS. 12 through 15 may be in a region to which the high voltage is applied more frequently than other regions in the nonvolatile memory device 30.

FIG. 17 illustrates an example of NBTI in a high voltage PMOS transistor 50 in a high voltage switch according to exemplary embodiments. Referring to FIG. 17, the high voltage PMOS transistor 50 includes a well 54 formed in a substrate, doping regions 52 and 53, and a gate electrode 51. In order to turn on the high voltage PMOS transistor 50, the ground voltage VSS is applied to the gate electrode 51, and the program turn-on voltage VPGM+α having a high voltage level is applied to the doping regions 52 and 53 and the well 54. In this case, an electric field EF is generated from a channel 55 between the doping regions 52 and 53 to the gate electrode 51. As time elapses while the electric field EF is being generated, the threshold voltage of the high voltage PMOS transistor 50 gradually increases due to the NBTI phenomenon. When the threshold voltage of the high voltage PMOS transistor 50 increases, circuit elements including the high voltage PMOS transistor 50 may have a lower operating speed and a degraded reliability.

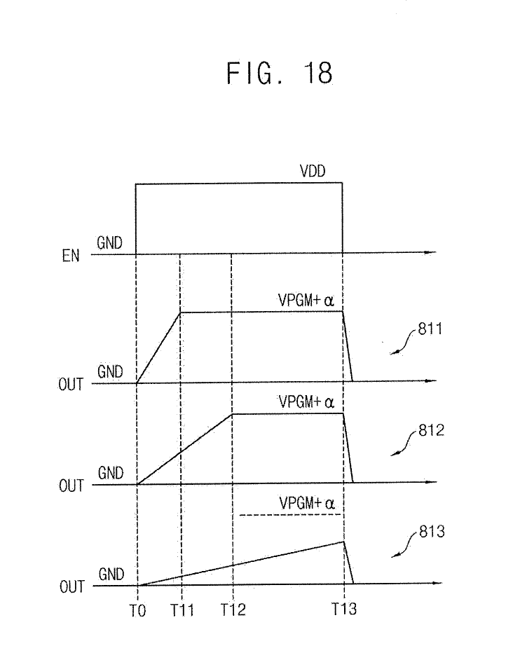

FIG. 18 illustrates an example of a switching characteristic of the high voltage PMOS transistor of FIG. 17 due to the NBTI. In FIG. 18, a voltage is provided at a drain of the doping region 53 (a drain) when the enable signal EN is applied to the gate 51, and the program turn-on voltage VPGM+α is applied to the doping region 52 (a source) in the high voltage PMOS transistor 50.

In FIG. 18, the enable signal EN applied to the gate 51 of the high voltage PMOS transistor 50 is activated with a power supply voltage VDD from a time point TO to a time point T13. Reference numeral 811 denotes a voltage OUT output from the drain 53 based on the program turn-on voltage VPGM+α applied to the source 52 in an initial state when the high voltage PMOS transistor does not experience the NBTI. Reference numeral 812 denotes the voltage OUT output from the drain 53 based on the program turn-on voltage VPGM+α applied to the source 52 when the high voltage PMOS transistor experiences a stress due to the NBTI during a first time interval. Reference numeral 813 denotes the voltage OUT output from the drain 53 based on the program turn-on voltage VPGM+α applied to the source 52 when the high voltage PMOS transistor experiences a stress due to the NBTI during a second time interval greater than the first time interval.

As illustrated by reference numeral 811, when the high voltage PMOS transistor 50 does not experience NBTI, the voltage OUT output from the drain 53 based on the enable signal EN has a level of the program turn-on voltage VPGM+α at a time point T11. As illustrated by reference numeral 812, when the high voltage PMOS transistor 50 experience NBTI during the first time interval, the voltage OUT output from the drain 53 based on the enable signal EN has a level of the program turn-on voltage VPGM+α at a time point T12. However, as illustrated by reference numeral 813, when the high voltage PMOS transistor 50 experience the NBTI during the second time interval, the voltage OUT output from the drain 53 based on the enable signal EN does not have a level of the program turn-on voltage VPGM+α after a time point T13.

Therefore, a switching characteristic of the high voltage PMOS transistor 50 is degraded due to a degradation of the threshold voltage of the high voltage PMOS transistor 50 due to NBTI, and performance of circuit elements including the high voltage PMOS transistor 50 is degraded.

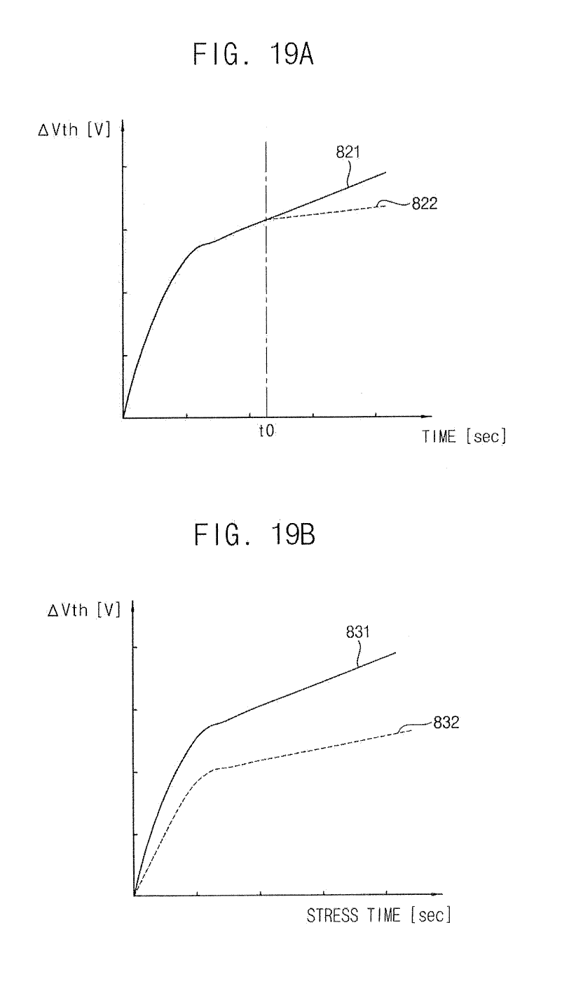

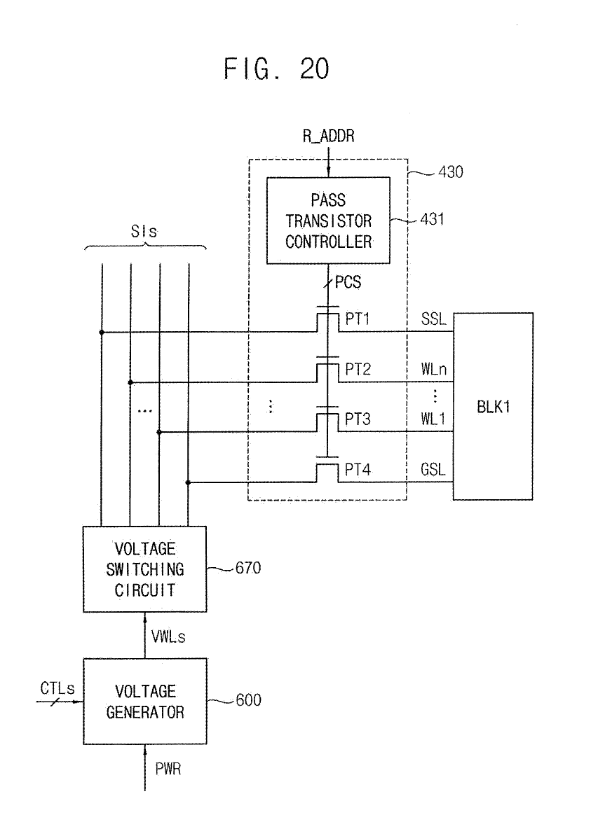

FIG. 19A illustrates an example of the performance of the high voltage switch circuit of FIG. 12. In this example, an increased amount of threshold voltage ΔVth of the high voltage PMOS transistor, which is generated by stress due to NBTI, is shown, in a first case when the high voltage switch 720 in FIG. 12 includes one high voltage PMOS transistor, and in a second case when the high voltage switch 720 in FIG. 12 includes two high voltage PMOS transistors. In FIG. 19A, reference numeral 821 denotes the first case when the high voltage switch 720 includes one high voltage PMOS transistor. Reference numeral 822 denotes second case when the high voltage switch includes two high voltage PMOS transistors.

Referring to FIG. 19A, as the number of high voltage PMOS transistors in the high voltage switch 720 increases, the degree to which the degree of threshold voltage ΔVth of each high voltage PMOS transistor increases is decreased. Also, in FIG. 19A, the first high voltage PMOS transistor 722 is selected until a time point t0 and the second high voltage PMOS transistor 723 is selected after the time point t0.

FIG. 19B illustrates an example of the performance of the high voltage switch circuits of FIGS. 13 and 14 according to exemplary embodiments. In FIG. 19B, an increased amount of threshold voltage ΔVth of the high voltage PMOS transistor, which is generated according to stress time due to NBTI, occurs in two cases. The first case involves when high voltage switch 720 in FIGS. 12 and 13 uses the above-mentioned scheme based on the program/erase cycles or the degradation degree of the reference memory cell. The second case involves when the high voltage switch 720 in FIGS. 12 and 13 does not use the above-mentioned scheme.

In FIG. 19B, reference numeral 831 denotes the first case when the high voltage switch 720 includes one high voltage PMOS transistor and does not use the scheme. Reference numeral 832 denotes second case when the high voltage switch includes two high voltage PMOS transistors and uses the scheme. Referring to FIG. 19B, the increased degree of threshold voltage ΔVth of each high voltage PMOS transistor is decreased when the high voltage switch 720 uses the scheme.

FIG. 20 illustrates an embodiment of a portion of the nonvolatile memory device of FIG. 3 according to exemplary embodiments. The nonvolatile memory device includes a first memory block BLK1 of the memory cell array 100, the address decoder 430, the voltage generator 600, and the voltage switching circuit 670.

Referring to FIG. 20, the address decoder 430 is coupled to the voltage switching circuit 670 through a plurality of selection lines S. The address decoder 430 includes a pass transistor controller 431 and a plurality of pass transistors PT1˜PT4 coupled to the string selection line SSL, word-lines WL1˜WLn, and ground selection line GSL of the first memory block BLK. The pass transistor controller 431 applies control signals PCS to the pass transistors PT1˜PT4 based on the row address R_ADDR, such that the word-line voltage VWLs from the voltage switching circuit 670 are transferred to the first memory block BLK1.

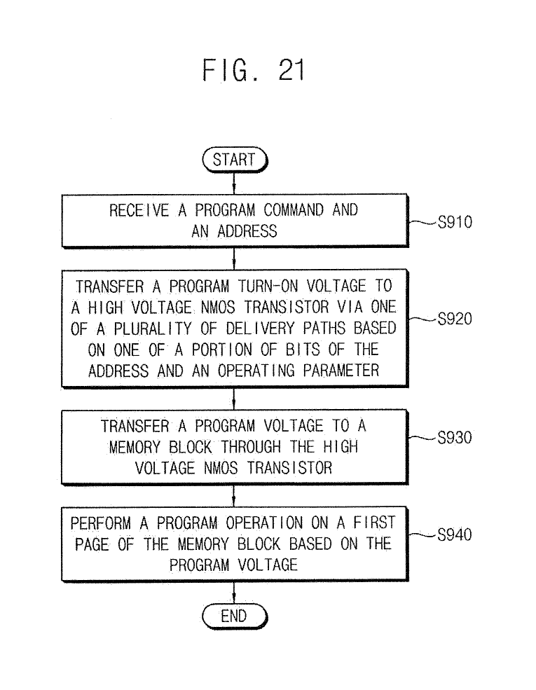

FIG. 21 illustrates an embodiment of a method for operating a nonvolatile memory device, which, for example, may be nonvolatile memory device 40 in FIG. 3.

Referring to FIGS. 3 through 21, according to this method, the nonvolatile memory device 30 receives the program command CMD and the address ADDR from the memory controller (S910). The high voltage switch circuit 700 transfers the program turn-on voltage VPGM+α to at least one high voltage NMOS transistor via one of a plurality of delivery paths based on a portion of bits of the address ADDR or an operating parameter of the nonvolatile memory device 30 (S920). The at least one high voltage NMOS transistor transfers a program voltage VPGM to a selected memory block of the memory blocks BLK1-BLKz based on the program turn-on voltage VPGM+α (S930). The nonvolatile memory device 30 performs a program operation on the selected memory block using the program voltage VPGM (S940).

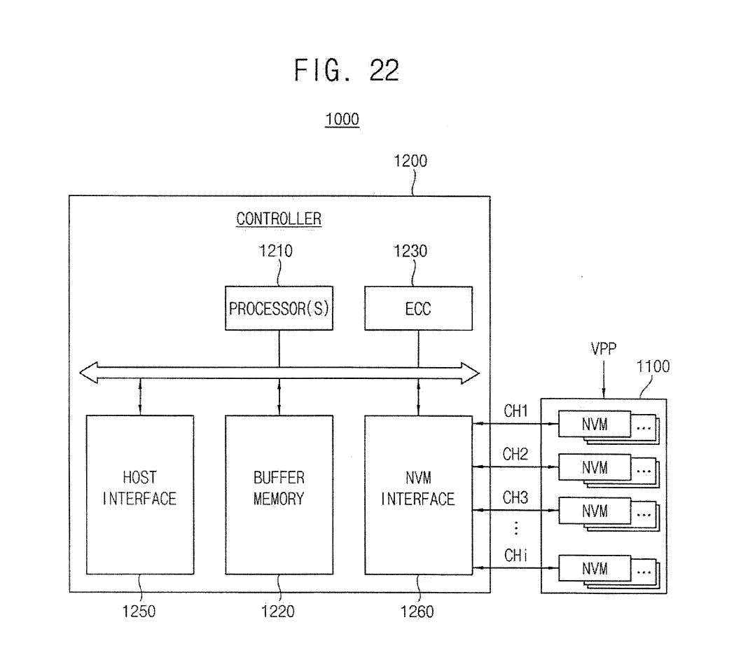

FIG. 22 illustrates an embodiment of a solid state disk or solid state drive (SSD) 1000 which includes multiple nonvolatile memory devices 1100 and an SSD controller 1200. The nonvolatile memory devices 1100 may be optionally supplied with an external high voltage VPP. Each of the nonvolatile memory devices 1100 may include the nonvolatile memory devices 1100 of FIG. 3. Therefore, each of the nonvolatile memory devices 1100 transfers the program turn-on voltage VPGM+α via one of a plurality of delivery paths based on a portion of bits of the address or an operating parameter of the nonvolatile memory devices 1100, such that degradation of the high voltage PMOS transistor due to the NBTI is dispersed to enhance performance.

The SSD controller 1200 is connected to the nonvolatile memory devices 1100 through multiple channels CH1 to CHi. The SSD controller 1200 includes one or more processors 1210, a buffer memory 1220, an ECC block 1230, a host interface 1250, and a nonvolatile memory interface 1260. The buffer memory 1220 stores data used to drive the SSD controller 1200. The buffer memory 1220 comprises multiple memory lines each storing data or a command. The ECC block 1230 calculates error correction code values of data to be programmed at a writing operation and corrects an error of read data using an error correction code value at a read operation. In a data recovery operation, The ECC block 1230 corrects an error of data recovered from the nonvolatile memory devices 1100.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods described herein.

The controllers and control circuits, processors, decoders, counters, monitors, comparators, and other signal generating and signal processing features of the disclosed embodiments may be implemented in logic which, for example, may include hardware, software, or both. When implemented at least partially in hardware, the controllers, processors, decoders, counters, monitors, comparators, and other signal generating and signal processing features may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the controllers, processors, decoders, counters, monitors, comparators, and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. A high voltage switch circuit of a nonvolatile memory device including a plurality of memory blocks, the high voltage switch circuit comprising:
a high voltage n-channel metal-oxide semiconductor (NMOS) transistor to be turned-on based on a program turn-on voltage and to transfer a program voltage to a first memory block of the plurality of memory blocks;
a logic to generate path selection signals based on an enable signal and switching control signals based on one of an operating parameter of the nonvolatile memory device or an access address for at least a portion of the first memory block, the enable signal to be activated during a program operation on the first memory block; and
a high voltage switch to deliver the program turn-on voltage to a gate of the high voltage NMOS transistor via one of a plurality of delivery paths based on the path selection signals.

2. The high voltage switch circuit as claimed in claim 1, wherein the high voltage switch is to disperse an effect of a negative bias temperature instability generated by the program turn-on voltage, and
wherein the high voltage switch includes:
a depletion NMOS transistor having a first electrode to receive the program turn-on voltage and a gate connected to a first node connected to a gate of the high voltage NMOS transistor;
a first high voltage p-channel metal-oxide semiconductor (PMOS) transistor having a first electrode connected to a second electrode of the depletion NMOS transistor at a second node, a second electrode connected to the first node, and a gate to receive a first path selection signal of the selection signals; and
a second high voltage PMOS transistor having a first node connected to the second electrode of the depletion NMOS transistor at the second node, a second electrode connected to the first node, and a gate to receive a second path selection signal of the selection signals.

3. The high voltage switch circuit as claimed in claim 2, wherein:
the first high voltage PMOS transistor and the second high voltage PMOS transistor are connected in parallel between the first node and the second node,
a body of the first high voltage PMOS transistor is connected to the first electrode of the first high voltage PMOS transistor, and
a body of the second high voltage PMOS transistor is connected to the first electrode of the second high voltage PMOS transistor.

4. The high voltage switch circuit as claimed in claim 1, wherein:
the switching control signals are to reflect the access address, and
the logic includes:
a first NAND gate to output a first path selection signal based on the enable signal and at least one bit of the access address, wherein the first path selection signal is to be activated when the at least one bit has a first logic level; and
a second NAND gate to output a second path selection signal based on the enable signal and the at least one bit, wherein the second path selection signal is to be activated when the at least one bit has a second logic level different from the first logic level.

5. The high voltage switch circuit as claimed in claim 4, wherein the access address corresponds to a block address to select one of the memory blocks or a page address to select one of a plurality of pages in the first memory block.

6. The high voltage switch circuit as claimed in claim 1, wherein:
the switching control signals are to reflect the operating parameter,
the operating parameter corresponds to a program/erase cycle of the first memory block, and
the logic includes:
a first NAND gate to output a first path selection signal based on the enable signal and a first switching control signal, wherein the first path selection signal is to be activated when the first switching control signal indicates that the program/erase cycle belongs to a first range; and
a second NAND gate to output a second path selection signal based on the enable signal and a second switching control signal, wherein the second path selection signal is to be activated when the second switching control signal indicates that the program/erase cycle belongs to a second range greater than the first range.

7. The high voltage switch circuit as claimed in claim 6, wherein:
the logic is to activate the first path selection signal when the program/erase cycle belongs to a third range greater than the second range, and
the logic is to activate the second path selection signal when the program/erase cycle belongs to a fourth range greater than the third range.

8. The high voltage switch circuit as claimed in claim 1, wherein:
the switching control signals are to reflect the operating parameter,
the operating parameter corresponds to a stress index indicating a degradation degree of at least a reference memory cell of a plurality of nonvolatile memory cells in the first memory block, and
the logic includes:
a first NAND gate to output a first path selection signal based on the enable signal and a first switching control signal, wherein the first path selection signal is activated when the first switching control signal indicates that the degradation degree belongs to a first range; and
a second NAND gate to output a second path selection signal based on the enable signal and a second switching control signal, wherein the second path selection signal is activated when the second switching control signal indicates that the degradation degree belongs to a second range greater than the first range.

9. A nonvolatile memory device, comprising:
a memory cell array including memory blocks;
a voltage generator to generate word-line voltages to be applied to the memory cell array;
an address decoder connected to the memory cell array through word-lines;
a voltage switching circuit to transfer the word-line voltages to the address decoder; and
a controller to control the voltage generator, the voltage switching block, and the address decoder based on a command and an address, wherein the voltage switching circuit includes a high voltage switch circuit to deliver a program voltage and a program turn-on voltage from the voltage generator to a first memory block of the memory blocks, via one of delivery paths, based on an enable signal and switching control signals based on one of an operating parameter of the nonvolatile memory device and an access address for at least a portion of the first memory block, the enable signal to be activated during a program operation on the first memory block.

10. The nonvolatile memory device as claimed in claim 9, wherein the high voltage switch is to disperse an effect of a negative bias temperature instability generated by the program turn-on voltage, and
wherein the high voltage switch circuit includes:
a high voltage n-channel metal-oxide semiconductor (NMOS) transistor to be turned-on based on the program turn-on voltage and to transfer the program voltage the first memory block;
a logic to generate path selection signals based on the enable signal and the switching control signals; and
a high voltage switch to deliver the program turn-on voltage to a gate of the high voltage NMOS transistor via one of the delivery paths based on the path selection signals.

11. The nonvolatile memory device as claimed in claim 10, wherein the high voltage switch includes:
a depletion NMOS transistor having a first electrode to receive the program turn-on voltage and a gate connected to a first node connected to a gate of the high voltage NMOS transistor;
a first high voltage p-channel metal-oxide semiconductor (PMOS) transistor having a first electrode connected to a second electrode of the depletion NMOS transistor at a second node, a second electrode connected to the first node, and a gate to receive a first path selection signal of the selection signals; and
a second high voltage PMOS transistor having a first node connected to the second electrode of the depletion NMOS transistor at the second node, a second electrode connected to the first node, and a gate to receive a second path selection signal of the selection signals.

12. The nonvolatile memory device as claimed in claim 9, wherein the high voltage switch circuit includes:
a plurality of high voltage n-channel metal-oxide semiconductor (NMOS) transistors connected in parallel to a first selection line connected to the first memory block; and
a plurality of high voltage switches, wherein each of the plurality of high voltage switches are connected to a gate of a corresponding one of the high voltage NMOS transistors, are to receive a corresponding one of the plurality of switching control signals, and are to selectively to deliver the program turn-on voltage to the corresponding one of the high voltage NMOS transistors based on the corresponding one of the plurality of switching control signals, and
wherein a high voltage NMOS transistor of the high voltage NMOS transistors is to be turned on based on the corresponding one of the plurality of switching control signal and is to deliver the program voltage to the first memory block via the first selection line.

13. The nonvolatile memory device as claimed in claim 12, wherein each of the plurality of high voltage switches includes:
a NAND gate to perform a NAND operation on the enable signal and the corresponding one of the plurality of switching control signals to output a path selection signal;
a depletion NMOS transistor having a first electrode to receive the program turn-on voltage and a gate connected to a first node connected to a gate of the high voltage NMOS transistor;
a high voltage p-channel metal-oxide semiconductor (PMOS) transistor having a first electrode connected to a second electrode of the depletion NMOS transistor at a second node, a second electrode connected to the first node, and a gate to receive the path selection signal; and
an NMOS transistor that has a first electrode connected to the first node, a gate to receive the path selection signal, and a second electrode connected to a ground voltage.

14. The nonvolatile memory device as claimed in claim 9, wherein the controller includes:
a command decoder to decode the command to output a decoded command;
a control signal generator to generate the plurality of switching control signals based on the decoded command and to generate the enable signal to be activated when the decoded command designates the program operation; and
a high voltage switch controller to generate the plurality of switching control signals based on at least one of the decoded command, the address, or data read from at least a reference memory cell of a plurality of memory cells in the first memory block.

15. The nonvolatile memory device as claimed in claim 14, wherein:
each of the memory blocks includes a plurality of cell strings arranged vertically on a substrate;
the operation parameter corresponds to a program/erase cycle of the first memory block or a stress index indicating a degradation degree of the reference memory cell; and
the plurality of switching control signals are to reflect one of the program/erase cycle, the stress index, or the address.

16. An apparatus, comprising:
a first transistor to be turned-on based on a program turn-on voltage, the first transistor to transfer a program voltage to a first memory block of a nonvolatile memory device;
a logic to generate a plurality of path selection signals based on an enable signal and a plurality of switching control signals based on one of an operating parameter of the nonvolatile memory device or an access address for at least a portion of the first memory block, the enable signal to be activated during a program operation on the first memory block; and
a switch to deliver the program turn-on voltage to a gate of the first transistor via one of a plurality of delivery paths based on the plurality of path selection signals.

17. The apparatus as claimed in claim 16, wherein the switch is to disperse an effect of a negative bias temperature instability generated by the program turn-on voltage.

18. The apparatus as claimed in claim 16, wherein the program voltage is greater than a power supply voltage for the nonvolatile memory device.

19. The apparatus as claimed in claim 16, wherein the switch includes:
a second transistor having a first electrode to receive the program turn-on voltage and a gate connected to a first node connected to a gate of the first transistor;
a third transistor having a first electrode connected to a second electrode of the second transistor at a second node, a second electrode connected to the first node, and a gate to receive a first path selection signal of the plurality of selection signals; and
a fourth transistor having a first node connected to the second electrode of the depletion transistor at the second node, a second electrode connected to the first node, and a gate to receive a second path selection signal of the plurality of selection signals.

20. The apparatus as claimed in claim 19, wherein:
the first and second transistors have a first conductivity type, and
the third and fourth transistors have a second conductivity type different from the first conductivity type.
